(19) United States
(12) Patent Application Publication
(10) Pub. No.: US 2014/0185638 A1
(43) Pub. Date: Jul. 3, 2014

(54) OPTICAL MODULE

(71) Applicant: SAE Magnetics (H.K.) Ltd., Hong Kong (CN)

(72) Inventor: Takemasa TAMANUKI, Hong Kong (CN)

(73) Assignee: SAE Magnetics (H.K.) Ltd., Hong Kong (CN)

(21) Appl. No.: 14/200,826

(22) Filed: Mar. 7, 2014

Related U.S. Application Data
(62) Division of application No. 13/067,409, filed on May 31, 2011.

(30) Foreign Application Priority Data
Dec. 9, 2010 (CN) 201010580971.X

(51) Int. Cl. H01S 5/026

(52) U.S. Cl. CPC H01S 5/0261
USPC 372/38.02

(57) ABSTRACT

There are provided an optical module including a semiconductor laser including a P-side electrode and an N-side electrode, and a semiconductor laser driver circuit that drives the semiconductor laser so as to output an optical signal from the semiconductor laser according to a pattern of a differentially transmitted digital electric signal, and the semiconductor laser driver circuit includes a positive-side terminal and a negative-side terminal for differentially transmitted non-inverted data, and a positive-side terminal and a negative-side terminal for differentially transmitted inverted data, and one terminal for the non-inverted data is electrically connected to one electrode of the semiconductor laser, and the other terminal for the non-inverted data, one terminal for the inverted data and the other terminal for the inverted data each are connected to the other electrode of the semiconductor laser.

### CROSS REFERENCE TO RELATED APPLICATION

This application is a divisional of U.S. patent application Ser. No. 13/067,409, filed May 31, 2011, now pending, which claims priority to Chinese Patent Application No. 201010580971.X, filed Dec. 9, 2010, the entire contents of which are hereby incorporated by reference in this application.

### TECHNICAL FIELD

The present invention relates to an optical module used in an optical communication system, and in particular, to an optical module using a semiconductor laser that outputs an optical signal converted from an electric signal.

### BACKGROUND ART

As shown in, for example, FIG. 2 relating to Patent document 1, an optical module used in an optical communication system converts an electric signal into an optical signal by driving a semiconductor laser by means of a semiconductor laser driver IC and transmits data through an optical fiber cable by using the optical signal.

With a recent increase in channel capacity, there has emerged a need to increase the bit rate of the optical communication system, that is, to increase the modulation rate to drive the semiconductor laser. However, optical output waveform of the semiconductor laser can disadvantageously deteriorate due to occurrence of a pattern effect caused by modulation of the semiconductor laser at high speed. This problem will be described below with reference to FIG. 1 to FIG. 6.

FIG. 1 are views showing configuration of an optical module, FIG. 1(B) is a top view and FIG. 1(A) is a side view of the optical module. This optical module has a function of inputting a digital electric signal from outside through trace lines 651, 652 for data input and outputting a data sequence of the digital electric signal as a digital optical signal from a semiconductor laser 610 (electric-optical conversion function, O/E conversion function). Because this optical module has also a function of coupling light outputted from the semiconductor laser 610 to an optical fiber, an actual optical output is outputted from the optical fiber. Here, description of details of the optical fiber is omitted.

Specifically, non-inverted data (Data+ (D+)) and inverted data (Data− (D−)) of a differentially transmitted digital electric signal are inputted to a semiconductor laser driver IC 620 in the optical module through the trace lines, 651, 652, respectively. Then, the semiconductor laser driver IC 620 drives the semiconductor laser 610 so that a digital optical signal sequence corresponding to the data sequence of the digital electric signal is outputted from the semiconductor laser 610.

FIG. 2 is a view showing a connection state of the semiconductor laser 610 and the semiconductor laser driver IC 620 in the optical module shown in FIG. 1 and FIG. 3A is a circuit diagram of this region. Of the circuit diagram of FIG. 3A, FIG. 3B is a circuit diagram of the semiconductor laser driver IC 620 shown in FIG. 2 and FIG. 3C is a circuit diagram of the semiconductor laser 610.

As shown in FIG. 2, the semiconductor laser 610 is formed by laminating a P-side electrode 611, a P-type semiconductor 612, an active layer 613, an N-type semiconductor 614 and an N-side electrode 615 in this order from the top. The semiconductor laser driver IC 620 includes connection terminals 625, 626 to which the trace lines 651, 652 receiving inputs of the non-inverted data (D+) and the inverted data (D−) that correspond to a pattern of the differentially transmitted digital electric signal are connected, respectively, and connection terminals 621, 622, 623, 624 for inputting the inputted non-inverted data (D+) and inverted data (D−) to the semiconductor laser 610, etc. The connection terminal 621 is a positive terminal (positive-side terminal) for the non-inverted data (D+) and the connection terminal 622 is a negative terminal (negative-side terminal) for the non-inverted data (D+). The connection terminal 623 is a positive terminal (positive-side terminal) for the inverted data (D−) and the connection terminal 624 is a negative terminal (negative-side terminal) for the inverted data (D−).

Describing the connection state of the semiconductor laser 610 and the semiconductor laser driver IC 620, the positive terminal 621 for the non-inverted data (D+) in the semiconductor laser driver IC 620 is connected to the P-side electrode 611 in the semiconductor laser 610 and the negative terminal 622 for the non-inverted data (D+) is connected to the N-side electrode 615 in the semiconductor laser 610. The positive terminal 623 for the inverted data (D−) in the semiconductor laser driver IC 620 is connected to the negative terminal 624 for the inverted data (D−) through a resistor 630.

As shown in FIG. 3B, the semiconductor laser driver IC 620 is equipped with a differential switch circuit 662 constituted of two (a pair of) transistors. When a constant current circuit 661 inputs a DC current controlled to have a constant value to the switch circuit, according to data values (“1” or “0”) of the non-inverted data (Data+: D+) and the inverted data (Data−: D−), one transistor is put into a SW-ON state and the other transistor is put into a SW-OFF state. As a result, the current flows to the transistor in the SW-ON state.

That is, in the case of Data+=“1” (Data−=“0”), the current on the side of the semiconductor laser 610 is turned ON and the current on the side of the resistor 630 is turned OFF. Conversely, in the case of Data+=“0” (Data−=“1”), the current on the side of the semiconductor laser 610 is turned OFF and the current on the side of the resistor 630 is turned ON. Whereby, the digital optical signal sequence corresponding to the digital electric signal data sequence of the non-inverted data (Data+) of the differentially transmitted digital electric signal is outputted from a laser optical output window 610a in the semiconductor laser 610.
[Patent document 1] Unexamined Patent Publication No. 2008-235619

### SUMMARY OF THE INVENTION

However, in driving the semiconductor laser 610 in the above-mentioned optical module, the waveform of the optical signal outputted from the semiconductor laser 610 may deteriorate depending on the data sequence pattern of the digital data of the inputted signal, that is, the so-called pattern effect may occur. This problem, that is, a cause of the pattern effect will be described below.

For purpose of illustration, FIG. 4 shows a connection circuit of the semiconductor laser 610 and the semiconductor laser driver IC 620 that constitute the optical communication module shown in FIG. 1. As shown by symbols S1, S2 in this figure, the semiconductor laser 610 and the semiconductor laser driver IC 620 are electrically connected with each other via bonding wires 641 to 644 and an AC current flows to this region. Because an inductance component is parasitic on the bonding wires, when the AC current flows to this region, a potential difference between both ends of each bonding wire is generated. In other words, excessive impedance occurs in the bonding wires.

Here, noting the bonding wire represented by a reference numeral 642, excessive impedance occurring in the bonding wire 642 causes a potential difference between a ground terminal G and the N-side electrode in the semiconductor laser 610. Then, a value of a current that should be passed to the semiconductor laser 610 decreases due to the impedance, resulting in that the optical signal outputted from the semiconductor laser 610 is disadvantageously decreased (deteriorated).

Especially as the transmission capacity (that is, bit rate) of the optical communication module increases, the modulation rate of the semiconductor laser 610 also needs to be increased and therefore, the above-mentioned optical signal deterioration problem becomes more prominent. That is, when the AC current flows to the inductance, excessive impedance occurs in the inductance and thus, as a frequency becomes higher, the current is harder to flow. This phenomenon will be described below with reference to FIG. 5.

First, as shown in FIG. 5, when the AC current flows to the inductance, a potential difference (voltage) V(t)=L·dI(t)/dt is generated between both ends of the inductance. When defining the AC current as a sinusoidal current and describing as I(t)=I0·exp(jωt) (j: imaginary, I0: amplitude signal, ω: angular frequency of AC current, t: time), the voltage is expressed as V(t)=L·dI(t)/dt=jωLI(t) and impedance Z of the AC current in the inductance L is expressed as Z=V(t)/I(t)=jωL. This reveals that as the frequency of AC current is higher (ω is larger), the impedance Z becomes larger and the current is harder to flow.

Continuously, description is made with reference to FIGS. 6(A) to (D). FIGS. 6(A) to (D) are explanation views showing relationship between the data sequence of the digital input signal and the optical output waveform (especially, optical output intensity) from the semiconductor laser in the optical module (transverse axis: time, vertical axis: optical output intensity).

FIG. 6(A) shows the optical output waveform in the case of the data sequence of the input signal “0,0,0, . . . , 0”, and the optical output in this case is at a second optical output level (L2) all the time. Next, FIG. 6(B) shows the optical output waveform in the case of the data sequence of the input signal “1,1,1, . . . , 1”, and the optical output in this case is at a first optical output level (L1) all the time.

Next, FIG. 6(C) shows the optical output waveform in the case of the data sequence of the input signal “1,1,0,0,1,1,0,0, . . . ”, and in this case, the optical output corresponding to the data “1” is at a third optical output level (L3). The third optical output level is lower than the first optical output level. The reason is as follows: since the AC current flows to the semiconductor laser and impedance occurs in the bonding wires, the current flowing to the semiconductor laser decreases. Thus, the optical output intensity at the level of the data “1” lowers.

FIG. 6(D) shows the optical output waveform in the case of the data sequence of the input signal “1,0,1,0,1,0,1,0, . . . ”, and in this case, the optical output corresponding to the data “1” is in a fourth optical output level (L4) and the fourth optical output level is lower than the third optical output level. This is due to that the frequency in the data sequence of the input signal in FIG. 6(D) is higher than that in FIG. 6C. As described above with reference to FIG. 5, as the frequency is higher, the impedance occurred in the bonding wires becomes higher, leading to further reduction of the current flowing to the semiconductor laser.

The periodic data sequence of the input signal has described above. However, because “1” and “0” are randomly aligned in the data sequence in the actual input signal, the semiconductor laser is driven with various frequencies and accordingly, the waveform of the semiconductor laser deteriorates. As a result, there occurs the pattern effect that the optical output waveform deteriorates due to the input data sequence pattern. Note that the above-mentioned “AC current” is not a so-called sinusoidal current, but a so-called “data current” (or “modulated current”) according to the digital data sequence.

In consideration of such circumstances, an object of the present invention is to solve the above-mentioned problem, that is, deterioration of the optical output waveform due to the pattern effect that can occur in the semiconductor laser while increasing the transmission capacity of the optical module.

In order to attain the above-mentioned object, an optical module from one aspect of the present invention including:

a semiconductor laser having a P-side electrode and an N-side electrode; and

a semiconductor laser driver circuit that drives the semiconductor laser so as to output an optical signal from the semiconductor laser according to a pattern of a differentially transmitted digital electric signal, wherein

the semiconductor laser driver circuit has a positive-side terminal and a negative-side terminal for differentially transmitted non-inverted data, and a positive-side terminal and a negative-side terminal for differentially transmitted inverted data, and

one terminal for the non-inverted data is electrically connected to one electrode of the semiconductor laser, and the other terminal for the non-inverted data, one terminal for the inverted data and the other terminal for the inverted data each are connected to the other electrode of the semiconductor laser.

In the optical module,

the terminals in the semiconductor laser driver circuit each are connected to the corresponding electrode of the semiconductor laser via a signal line having a predetermined length.

In the optical module with the above-mentioned configuration, one of the positive-side terminal and the negative-side terminal for the non-inverted data in the semiconductor laser driver circuit is electrically connected to one of the P-side electrode and the N-side electrode in the semiconductor laser, and the other terminal for the non-inverted data is electrically connected to the other electrode in the semiconductor laser. One and the other terminals for the inverted data in the semiconductor laser driver circuit each are connected to the other electrode in the semiconductor laser. Whereby, the optical signal according to the pattern of the differentially transmitted digital electric signal is outputted from the semiconductor laser.

According to the present invention, especially since the terminals for the inverted data each are connected to the other electrode in the semiconductor laser, a DC current flows between the other electrode in the semiconductor laser and the other terminal for the non-inverted data, and between the other electrode in the semiconductor laser and the other terminal for the inverted data. Thus, even when they are connected to each other via the signal lines having the predetermined length, impedance occurring in the signal lines becomes 0. Thus, even when the frequency becomes high, a decrease in a value of the flowing current can be suppressed. As a result, deterioration of the optical output waveform due to the pattern effect that can occur in the semiconductor laser can be prevented while increasing transmission capacity of the optical module.

In the optical module,

an electronic component having a predetermined resistance value is electrically connected between one terminal for the inverted data that has the same polarity as one terminal for the non-inverted data in the semiconductor laser driver circuit, the one terminal for the non-inverted data being connected to the one electrode in the semiconductor laser, and the other electrode in the semiconductor laser.

For example, the electronic component is a resistor having a resistance value corresponding to that of the semiconductor laser. Alternatively, the electronic component is another semiconductor laser having the same characteristics as the initial semiconductor laser. Alternatively, the electronic component is a Peltier element. The Peltier element is arranged on a back surface of a substrate on which the semiconductor laser is mounted at the opposite side of the semiconductor laser mounting position, is electrically connected to the one terminal for the inverted data via a through-hole electrode formed on the substrate, and is electrically connected to the other electrode in the semiconductor laser. A heat-absorbing part constituting the Peltier element is brought into contact with the back surface of the substrate at the opposite side of the semiconductor laser mounting position, and a heat-generating part constituting the Peltier element is provided with a heat-radiating plate.

As described above, by providing the resistor or another semiconductor laser that has the same resistance value or characteristics as the semiconductor laser provided on the side of non-inverted data, or the electronic component having the predetermined resistance value such as the Peltier element, on the signal line for the inverted data, the signal lines for the non-inverted data and the inverted data have the same resistance value. Thus, operation of the circuit is stabilized and waveform characteristics of the optical output can be improved. When the Peltier element is provided as described above, the semiconductor laser can be cooled, thereby improving reliability of the optical module itself.

In the optical module, for example,

the one electrode in the semiconductor laser is the P-side electrode and the other electrode is the N-side electrode,

the one terminal for the non-inverted data in the semiconductor laser driver circuit is the positive-side terminal and the other terminal for the non-inverted data in the semiconductor laser driver circuit is the negative-side terminal, and

the one terminal for the inverted data in the semiconductor laser driver circuit is the positive-side terminal and the other terminal for the inverted data in the semiconductor laser driver circuit is the negative-side terminal.

In the optical module, for example,

the one electrode in the semiconductor laser is the N-side electrode and the other electrode is the P-side electrode,

the one terminal for the non-inverted data in the semiconductor laser driver circuit is the negative-side terminal and the other terminal for the non-inverted data in the semiconductor laser driver circuit is the positive-side terminal, and

the one terminal for the inverted data in the semiconductor laser driver circuit is the negative-side terminal and the other terminal for the inverted data in the semiconductor laser driver circuit is the positive-side terminal.

In the optical module,

a light-receiving element is provided adjacent to the semiconductor laser, the light-receiving element being electrically connected to the semiconductor laser driver circuit.

With the above-mentioned configuration, since the DC current, not AC current, flows to the electrodes in the semiconductor laser, occurrence of electromagnetic wave can be prevented. For this reason, even when the semiconductor laser and the light-receiving element are arranged adjacent to each other, increasing reception sensitivity of the light-receiving element can be prevented. Therefore, it is possible to improve performances of the optical module while achieving reduction of the optical module in size.

A parallel-arranged type optical module from another aspect of the present invention has configuration in which the plurality of above-mentioned optical modules are arranged in parallel. In the parallel-arranged type optical module, the other electrode in the optical modules is formed of a common electrode.

Even when the plurality of optical modules are arranged in parallel as described above, the potential between the other electrodes in the optical modules can be kept constant. Therefore, electro magnetic interference crosstalk (EMI-crosstalk) can be prevented from occurring between the optical modules, thereby suppressing deterioration of the optical waveform.

According to the present invention, with such configuration, deterioration of the optical output waveform due to the pattern effect that can occur in the semiconductor laser can be prevented while increasing the transmission capacity of the optical module.

### BRIEF DESCRIPTION OF DRAWINGS

FIG. 1 is a view showing configuration of an optical module relating to the present invention;

FIG. 2 is a view showing a part of the configuration of the optical module shown in FIG. 1;

FIG. 3A is a circuit diagram of the optical module shown in FIG. 1;

FIG. 3B is a circuit diagram showing a part of the optical module shown in FIG. 3A;

FIG. 3C is a circuit diagram showing a part of the optical module shown in FIG. 3A;

FIG. 4 is a view for explaining a problem of the configuration of the optical module shown in FIG. 1;

FIG. 5 is a view for explaining the problem of the configuration of the optical module shown in FIG. 1;

FIG. 6 is a view showing an example of an optical signal outputted from the optical module shown in FIG. 1;

FIG. 7 is a view showing configuration of an optical module in accordance with First embodiment of the present invention;

FIG. 8 is a view showing a part of the configuration of the optical module shown in FIG. 7;

FIG. 9 is a circuit diagram showing a part of the optical module shown in FIG. 7;

FIG. 10 is a view showing a modification example of the configuration of the optical module in accordance with First embodiment of the present invention;

FIG. 11 is a view showing a modification example of the configuration of the optical module in accordance with First embodiment of the present invention;

FIG. 12 is a view showing a modification example of the configuration of the optical module in accordance with First embodiment of the present invention;

FIG. 13 is a circuit diagram showing a modification example of the configuration of the optical module in accordance with First embodiment of the present invention;

FIG. 14 is a view showing configuration of another optical module to be compared with a parallel-arranged type optical module in accordance with Second embodiment of the present invention;

FIG. 15 is a view showing configuration of still another optical module to be compared with the parallel-arranged type optical module in accordance with Second embodiment of the present invention;

FIG. 16 is a view showing configuration of still another optical module to be compared with the parallel-arranged type optical module in accordance with Second embodiment of the present invention;

FIG. 17 is a view showing configuration of still another optical module to be compared with the parallel-arranged type optical module in accordance with Second embodiment of the present invention;

FIG. 18 is a circuit diagram of the parallel-arranged type optical module shown in FIG. 17;

FIG. 19 is a view showing configuration of the parallel-arranged type optical module in accordance with Second embodiment of the present invention;

FIG. 20 is a view showing configuration of an optical module in accordance with Third embodiment of the present invention; and

FIG. 21 is a view showing configuration of another optical module to be compared with the parallel-arranged type optical module shown in FIG. 20.

### DETAILED DESCRIPTION OF PREFERRED EMBODIMENTS

### First Embodiment

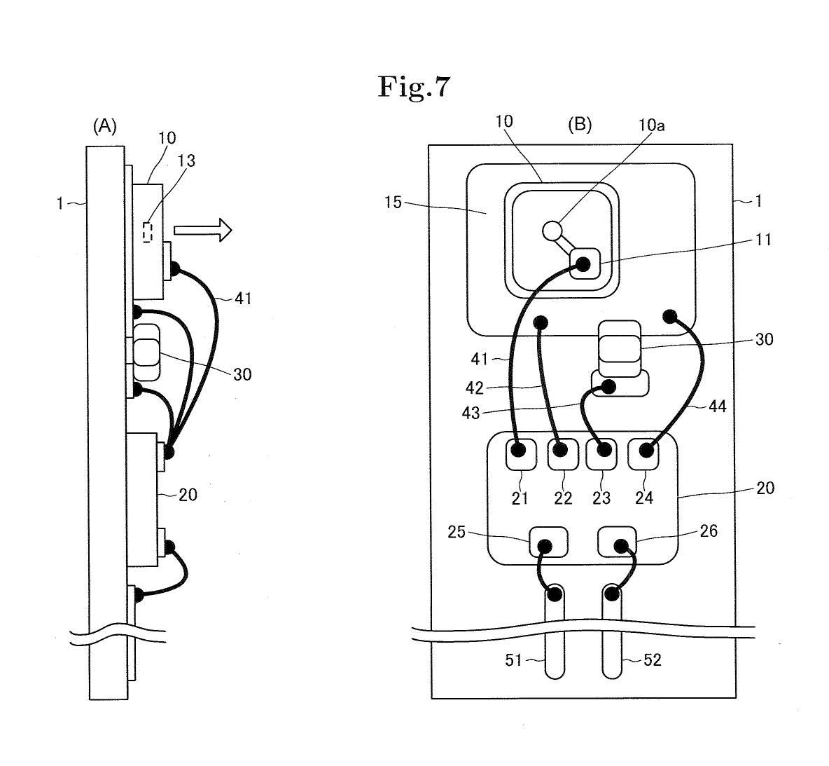

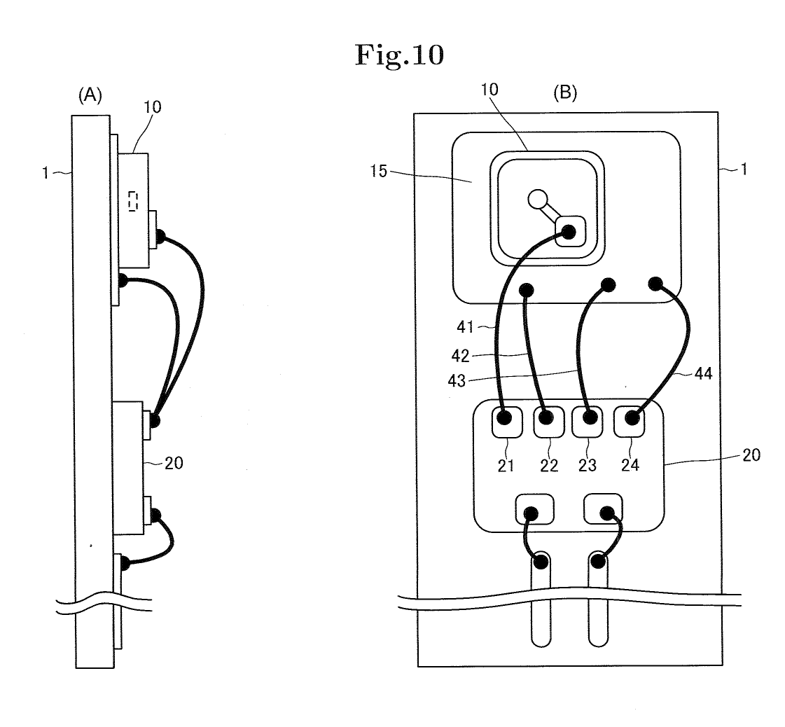

First embodiment of the present invention will be described below with reference to FIG. 7 to FIG. 13. FIG. 7 to FIG. 9 are view showing configuration of an optical module in accordance with this embodiment and FIG. 10 to FIG. 13 are view showing modification examples of the optical module.

The optical module 1 of the present invention is used in an optical communication system. Specifically, as shown in a top view of FIG. 7(A) and a side view of FIG. 7(B), the optical module includes a semiconductor laser 10 and a semiconductor laser driver IC (circuit) 20 on a substrate 1. By driving the semiconductor laser 10 by means of the semiconductor laser driver IC (circuit) 20, an electric signal is converted into an optical signal on an active layer 13, and using the optical signal outputted from a laser beam exit window 10a as represented by an arrow, data is transmitted via an optical fiber cable (not shown). The optical module in this embodiment may function as a light transmitter or as a light transmitter-receiver having a light-receiving element as described later.

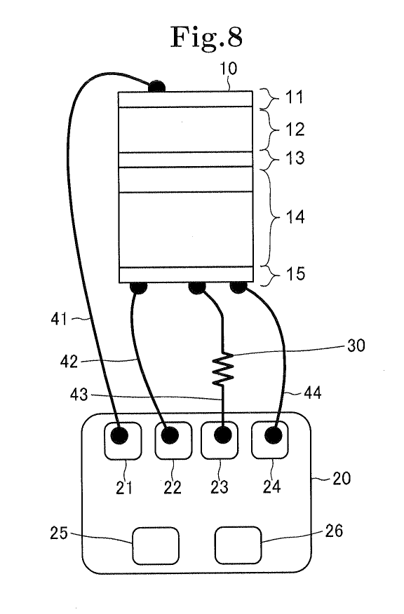

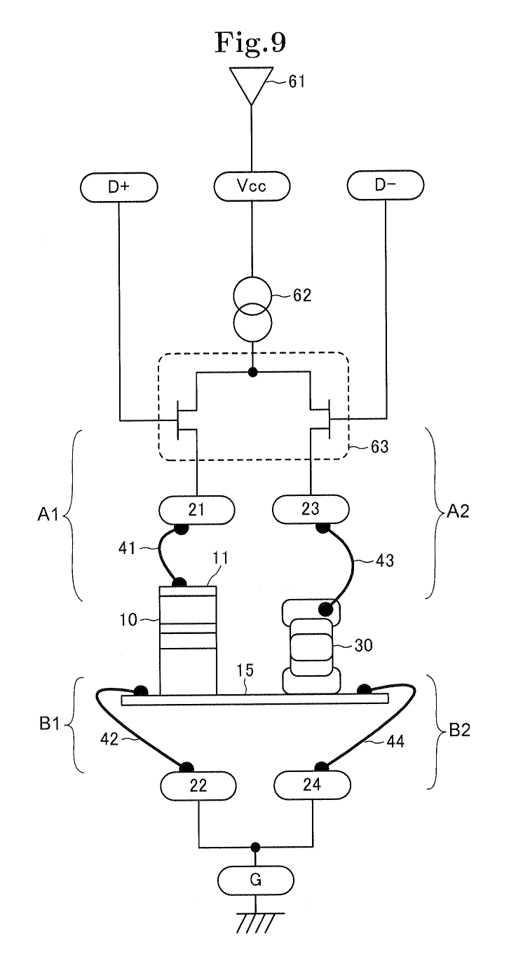

Specific configuration of the optical module in this embodiment will be further described below. FIG. 8 is a view showing a connection state of the semiconductor laser 10 and the semiconductor laser driver IC 20 in the optical module shown in FIG. 7 and FIG. 9 is a circuit diagram showing a part of the configuration.

As shown in FIG. 8, the semiconductor laser 10 is formed by laminating a P-side electrode 11, a P-type semiconductor 12, the active layer 13, an N-type semiconductor 14 and an N-side electrode 15 in this order from the top. The semiconductor laser driver IC 20 includes connection terminals 25, 26 to which trace line 51, 52 receiving inputs of non-inverted data (D+) and inverted data (D−) that correspond to a pattern of a differentially transmitted digital electric signal are connected, and connection terminals 21, 22, 23, 24 for inputting the inputted non-inverted data (D+) and inverted data (D−) to the semiconductor laser 10, etc. The connection terminal 21 is a positive terminal (positive-side terminal) for the non-inverted data (D+) and the connection terminal 22 is a negative terminal (negative-side terminal) for the non-inverted data (D+). The connection terminal 23 is a positive terminal (positive-side terminal) for the inverted data (D−) and the connection terminal 24 is a negative terminal (negative-side terminal) for the inverted data (D−).

As shown in FIG. 9, the semiconductor laser driver IC 20 is connected to a DC bias power source 61 and a constant current circuit 62, and has a differential switch circuit 63 constituted of two (a pair of) transistors to which a DC current controlled so as to have a constant value is inputted. Data values (“1” or “0”) are inputted from the differentially transmitted non-inverted data (D+) and inverted data (D−) to the differential switch circuit 63 through the connection terminals 25, 26, and according to the inputted data values, one transistor is put into the SW-ON state and the other transistor is put into the SW-OFF state, resulting in that the current flows to the transistor in the SW-ON state. Whereby, the digital optical signal sequence corresponding to the digital electric signal data sequence of the non-inverted data (Data+) of the differentially transmitted digital electric signal is outputted from the semiconductor laser 10. In FIG. 9, “D+” represents an input terminal for the non-inverted data, “D−” represent an input terminal for the inverted data, “Vcc” represents a DC bias terminal and “G” represents a ground terminal.

The electrical connection state of the semiconductor laser 10 and the semiconductor laser driver IC 20 will be described below with reference to FIG. 8 and FIG. 9. First, the positive terminal 21 for the non-inverted data (D+) in the semiconductor laser driver IC 20 is connected to the P-side electrode 11 in the semiconductor laser 10 and the negative terminal 22 for the non-inverted data (D+) is connected to the N-side electrode 15 in the semiconductor laser 10. The positive terminal 23 for the inverted data (D−) in the semiconductor laser driver IC 20 is connected to the N-side electrode 15 in the semiconductor laser 10 through a resistor 30 and the negative terminal 24 for the inverted data (D−) is also connected to the N-side electrode 15 in the semiconductor laser 10. That is, the negative terminal 22 for the non-inverted data (D+), the positive terminal 23 for the inverted data (D−) (through the resistor 30) and the negative terminal 24 for the inverted data (D−) are connected to the N-side electrode 15 in the semiconductor laser 10.

Each of the terminals 21 to 24 are connected to each of the electrodes 11, 15 in the semiconductor laser 10 and the resistor 30 via corresponding one of bonding wires 41 to 44 each having a predetermined length. However, the terminals are not necessarily connected via the bonding wires 41 to 44 and may be connected via other signal lines such as trace wires.

A resistance value of the resistor 30 is the same as that of the semiconductor laser 10, for example. Thus, since the signal lines for the non-inverted data (D+) and the inverted data (D−) have the same resistance value, operation of the circuit is stabilized. However, the resistance value of the resistor 30 is not necessarily the same as that of the semiconductor laser 10. Another electronic component having a predetermined resistance value may be provided in place of the resistor 30 as described later, or only the bonding wires may be used without providing another electronic component.

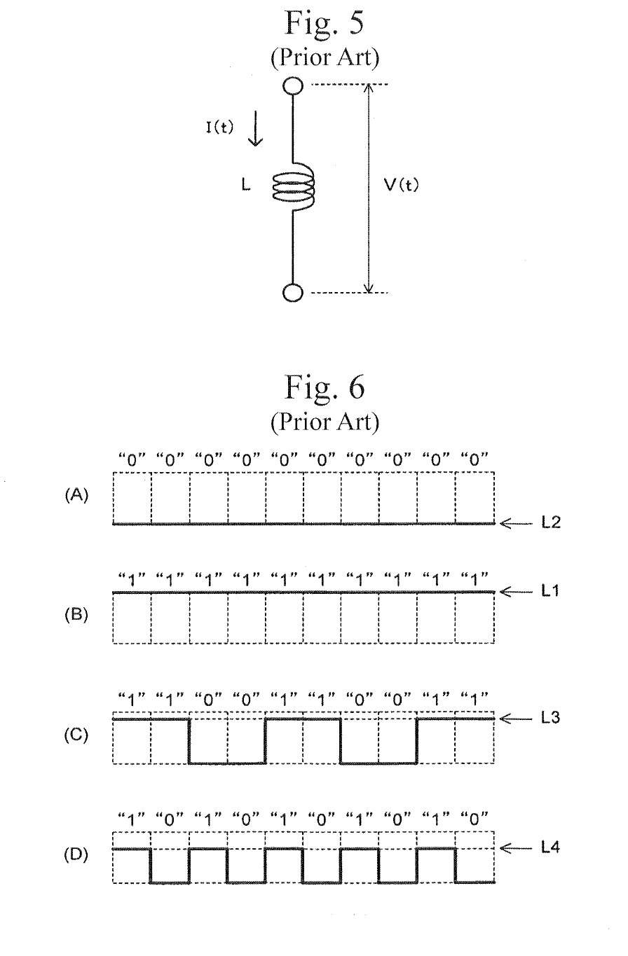

By connecting the semiconductor laser 10 to the semiconductor laser driver IC 20 as described above, an AC current flows to regions represented by a signal A1 and a signal A2 in FIG. 9, that is, the bonding wires 41, 43, while a DC current flows to regions represented by a signal B1 and a signal B2, that is, between the N-side electrode 15 in the semiconductor laser 10 and the negative terminal 22 for the non-inverted data (D+), and between the N-side electrode 15 in the semiconductor laser 10 and the negative terminal 24 for the inverted data (D−). Then, since the following relationship: dI(t)/dt=0 holds according to the expression described with reference with FIG. 5, impedance occurring in the bonding wires 42, 44 in the regions B1, B2 becomes “0”, resulting in that the potential of the N-side electrode 15 in the semiconductor laser 10 is kept constant irrespective of the inputted data pattern sequence.

Thus, even when the frequency of the inputted data pattern sequence becomes high, it is possible to prevent a value of the flowing current from decreasing, thereby reducing the probability of occurrence of the pattern effect. In this manner, deterioration of the optical output waveform due to the pattern effect that can occur in the semiconductor laser 10 can be prevented while increasing the transmission capacity of the optical module.

Modification examples of the optical module having the above-mentioned configuration will be described below with reference to FIG. 10 to FIG. 13. FIG. 10 show configuration of an optical module in First modification example of First embodiment, FIG. 10(A) is a top view and FIG. 10(B) is a side view of the optical module. The optical module shown in FIG. 10 has the substantially same configuration as the optical module shown in FIG. 7 except that the resistor 30 is not provided. In other words, in the optical module in FIG. 10, the N-side electrode 15 in the semiconductor laser 10 is directly connected to the positive terminal 23 for the inverted data (D−) in the semiconductor laser driver IC 20 via the bonding wire 43.

Also in this case, as described above, since the DC current flows between the N-side electrode 15 in the semiconductor laser 10 and the negative terminal 22 for the non-inverted data (D+), and between the N-side electrode 15 in the semiconductor laser 10 and the negative terminal 24 for the inverted data (D−), the probability of occurrence of the pattern effect can be reduced.

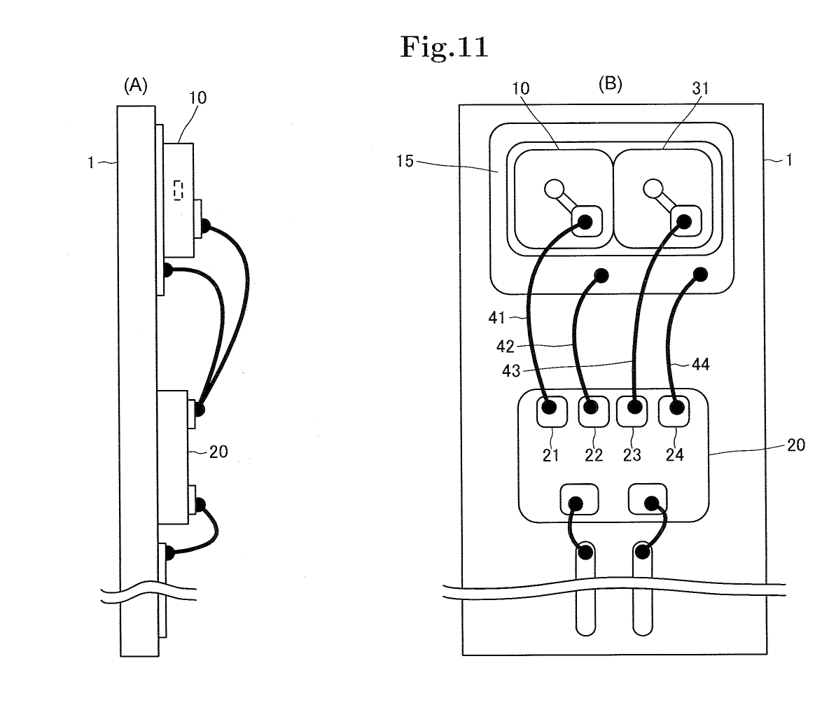

Next, FIG. 11 show configuration of an optical module in Second modification example of First embodiment, FIG. 11(A) is a top view and FIG. 11(B) is a side view of the optical module. The optical module shown in FIG. 11 has the substantially same configuration as the optical module shown in FIG. 7 except that, in place of the resistor 30, another dummy semiconductor laser 31 having the same characteristics as the semiconductor laser 10 is connected between the N-side electrode 15 in the semiconductor laser 10 and the positive terminal 23 for the inverted data (D−) in the semiconductor laser driver IC 20. The dummy semiconductor laser 31 does not output an optical signal in fact, or even when the dummy semiconductor laser 31 outputs the optical signal, the signal is not used.

Also in this case, as described above, since the DC current flows between the N-side electrode 15 in the semiconductor laser 10 and the negative terminal 22 for the non-inverted data (D+), and between the N-side electrode 15 in the semiconductor laser 10 and the negative terminal 24 for the inverted data (D−), the probability of occurrence of the pattern effect can be reduced. Especially since the signal lines of the non-inverted data (D+) and the inverted data (D−) have the same state, operation of the circuit is stabilized and waveform characteristics of the optical output can be improved.

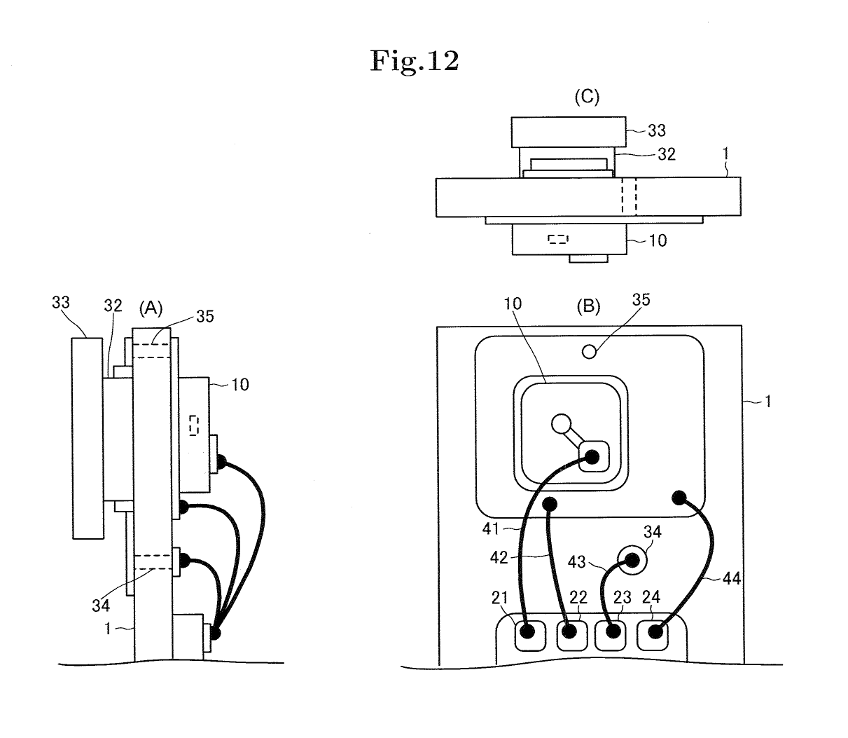

Next, FIG. 12 show configuration of an optical module in Third modification example of First embodiment, FIG. 12(A) is a top view and FIG. 12(B) is a side view of the optical module and FIG. 12(C) is a side view of an upper portion of FIG. 12(A). The optical module shown in FIG. 12 has the substantially same configuration as the optical module shown in FIG. 7 except that, in place of the resistor 30, a Peltier element 32 is connected between the N-side electrode 15 in the semiconductor laser 10 and the positive terminal 23 for the inverted data (D−) in the semiconductor laser driver IC 20.

Specifically, the Peltier element is arranged on a back surface of a substrate, the back surface being an opposite side of a front surface of the substrate on which the semiconductor laser is mounted, so as to be located corresponding to the semiconductor laser, in particular, on just at the back of the mounting position of the semiconductor laser 10. A heat-absorbing part of the Peltier element 32 is in contact with the substrate 1. A heat-radiating plate 33 is provided in contact with a heat-generating part of the Peltier element 32, which is located on the opposite side of the heat-absorbing part of the Peltier element 32.

Through-hole electrodes 34, 35 are formed in the substrate 1 so that the front and back surfaces of the substrate can be electrically connected to each other. The Peltier element 32 is electrically connected to the positive terminal 23 for the inverted data (D−) in the semiconductor laser driver IC 20 via the through-hole electrode 34 and the bonding wire 43, and is electrically connected to the N-side electrode 15 in the semiconductor laser 10 via the through-hole electrode 35. In such manner, the N-side electrode 15 in the semiconductor laser 10 and the positive terminal 23 for the inverted data (D−) in the semiconductor laser driver IC 20 are connected to the semiconductor laser 10 via the bonding wire 43 and the Peltier element 32.

Also in this case, as described above, since the DC current flows between the N-side electrode 15 in the semiconductor laser 10 and the negative terminal 22 for the non-inverted data (D+), and between the N-side electrode 15 in the semiconductor laser 10 and the negative terminal 24 for the inverted data (D−), the probability of occurrence of the pattern effect can be reduced. Especially since the signal lines for the non-inverted data (D+) and the inverted data (D−) have the same state due to a resistance value of the Peltier element 32, operation of the circuit is stabilized. In addition, the semiconductor laser can be cooled by the Peltier element 32, thereby improving reliability of the optical module itself.

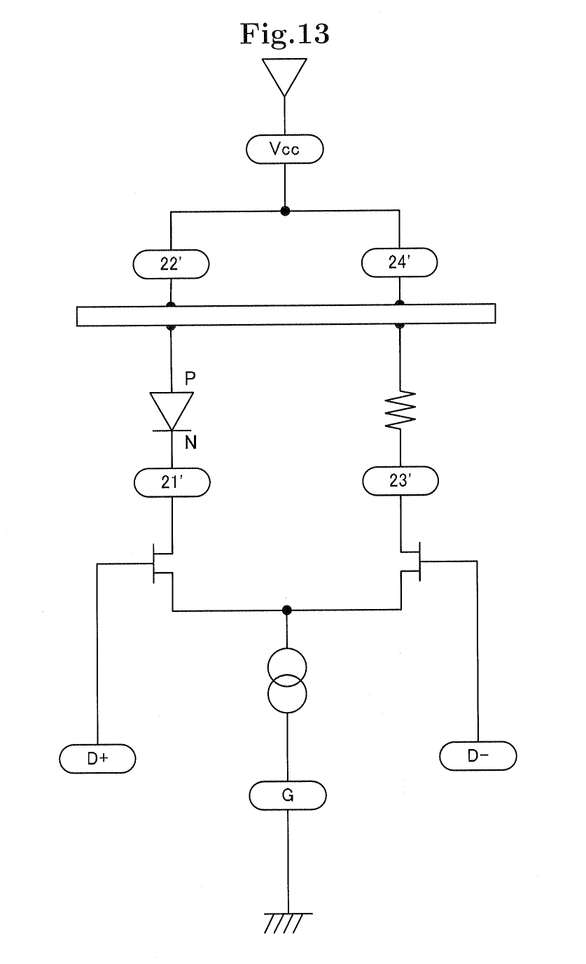

Next, FIG. 13 is a circuit of an optical module in Fourth modification example of First embodiment. The optical module shown in FIG. 13 is different from the optical module shown in FIG. 7 in that the P-side electrode and the N-side electrode in the semiconductor laser 10 are reversed and the positive terminal 21 and the negative terminal 22 for the non-inverted data (D+) and the inverted data (D−) in the semiconductor laser driver IC 20 are reversed. That is, the present invention can be applied to both the semiconductor laser with N-substrate and the semiconductor laser with P-substrate.

Specifically, FIG. 13 shows an electrical connection state of the semiconductor laser 10 and the semiconductor laser driver IC 20, in which a positive terminal 22′ for the non-inverted data (D+) in the semiconductor laser driver IC 20 is connected to the P-side electrode in the semiconductor laser 10 and a negative terminal 21′ for the non-inverted data (D+) is N-side electrode in the semiconductor laser 10. A positive terminal 24′ for the inverted data (D−) in the semiconductor laser driver IC 20 is connected to the P-side electrode in the semiconductor laser 10 and a negative terminal 23′ for the inverted data (D−) is connected to the P-side electrode in the semiconductor laser 10 via the resistor 30. In other words, each of the positive terminal 22′ for the non-inverted data (D+), the positive terminal 24′ for the inverted data (D−) and the negative terminal 23′ for the inverted data (D−) (via the resistor 30) is connected to the P-side electrode in the semiconductor laser 10. The resistor 30 is not necessarily provided. As in the First to Third modification examples, the dummy semiconductor laser or the Peltier element may be connected in place of the resistor 30, or only the bonding wires may be used without providing any electronic component.

Also in this case, since the DC current flows between the electrode in the semiconductor laser 10 and some of the terminals in the semiconductor laser driver IC 20, impedance at the regions becomes “0” and as described above, the probability of occurrence of the pattern effect can be reduced.

### Second Embodiment

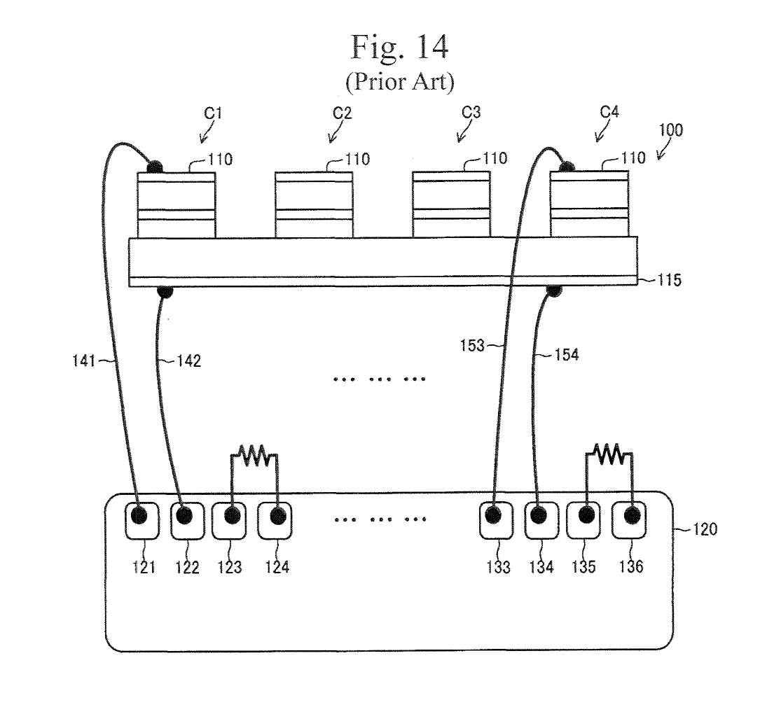

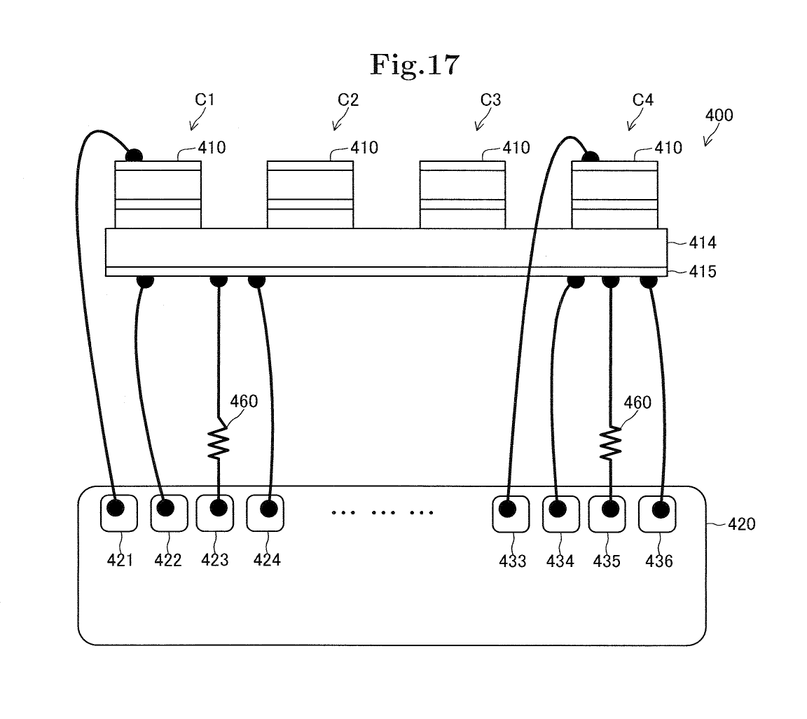

Next, Second embodiment of the present invention will be described below with reference to FIG. 14 to FIG. 19. FIG. 14 to FIG. 16 show configuration of parallel-arranged type optical modules to be compared with the optical module in accordance with this embodiment. FIG. 17 to FIG. 19 are views showing configuration of the parallel-arranged type optical modules in this embodiment.

The parallel-arranged type optical module in this embodiment includes a semiconductor laser array in which a plurality of optical modules in accordance with First embodiment are arranged in parallel. By using the plurality of optical modules parallelly-arranged in the optical communication system, the channel capacity in optical communication can be increased. For example, by configuring four channels of parallel-arranged type optical modules each having a channel capacity per channel of 10 Gb/s in optical communication, the optical module having the channel capacity of 40 Gb/s in total can be configured in whole.

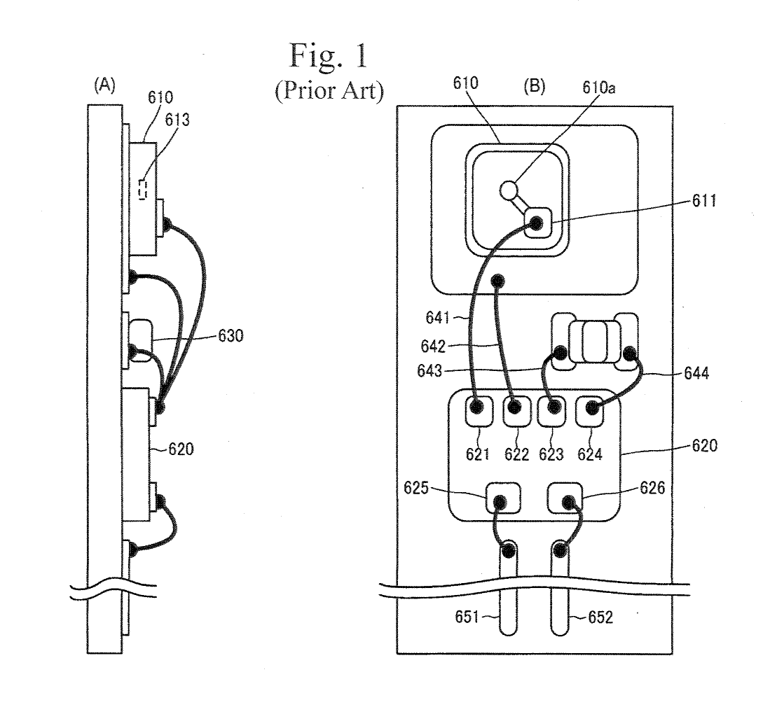

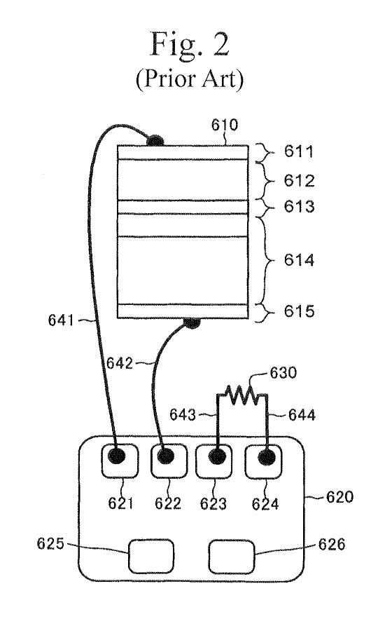

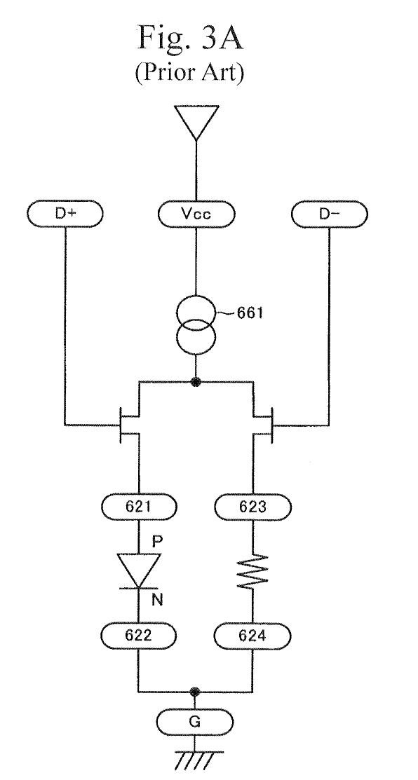

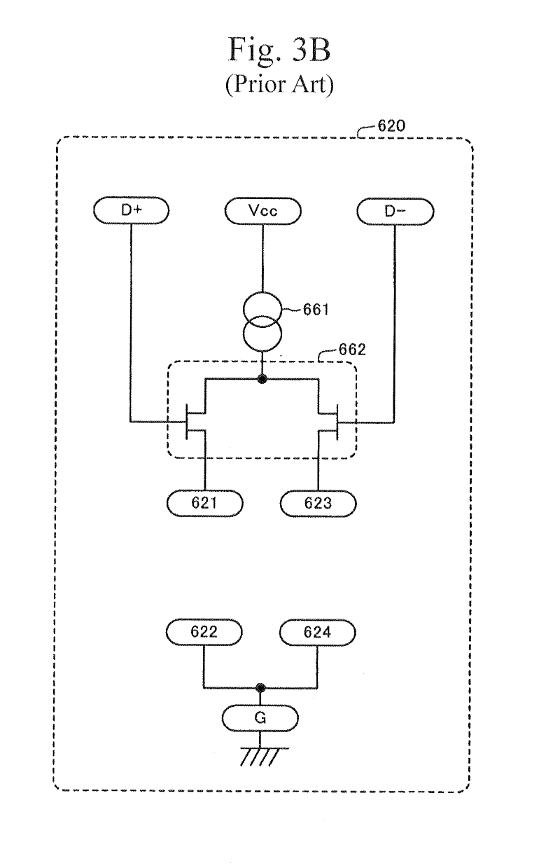

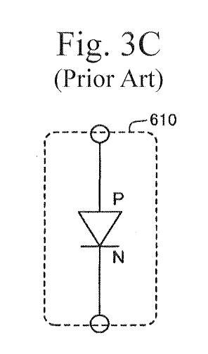

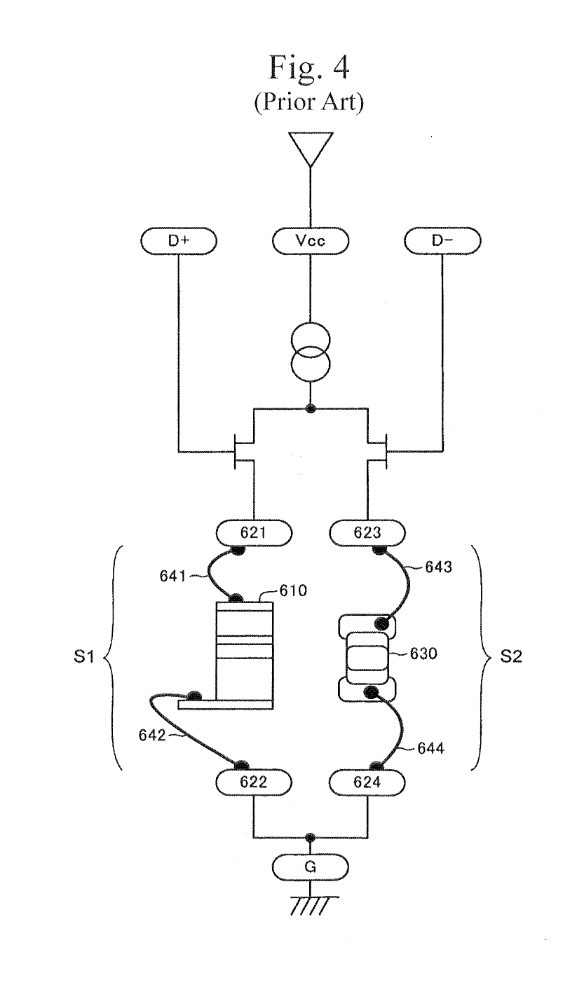

Here, configuration of the parallel-arranged type optical module to be compared with the parallel-arranged type optical module of the present invention will be described. The parallel-arranged type optical module for comparison in FIG. 14 includes the semiconductor laser array 100 in which the plurality of optical modules in FIG. 1, which is described in BACKGROUND ART, are arranged in parallel and an N-side electrode constitutes a common electrode. The parallel-arranged type optical module for comparison in FIG. 14 has four semiconductor lasers 110 to form a semiconductor laser array 100 of four channels C1 to C4. A semiconductor laser driver IC 120 is provided with terminals 121 to 136 connected to an electrode of each semiconductor laser 110.

The parallel-arranged type optical module for comparison in FIG. 14 has configuration in which the channels of the semiconductor lasers 110 are individually current-driven from corresponding positive terminals such as positive terminals 121, . . . , 133 for non-inverted data (D+) in the semiconductor laser driver IC 120. The semiconductor lasers shares the N-side electrode (common cathode structure) and the common N-side electrode is connected to each of the negative terminals 122, . . . , 134 for the non-inverted data (D+) in the semiconductor laser driver IC 120. Because the negative terminals 122, . . . , 134, for the non-inverted data (D+) in the semiconductor laser driver IC 120 each are a short circuit in the IC, the negative terminals 122, . . . , 134, “equipotential”.

However, when each channel of the semiconductor laser array 100 is driven according to independent data, an AC current flows to the N-side electrode 115 as the common electrode and bonding wires 142, . . . , 154 for connecting the terminals 122, . . . , 134 in the semiconductor laser driver IC 120 and a potential difference occurs between both ends of each of the bonding wires due to inductance components of the bonding wires 142, . . . , 154. Then, the potential of the N-side electrode 115 in the semiconductor laser array 100 varies according to a data pattern (data sequence) of each channel, thereby causing interference between the channels. This disadvantageously causes crosstalk between optical outputs of the channels.

For example, in FIG. 14, in the case where only the first channel C1 of the semiconductor laser array 100 is operated and the second to fourth channels C2 to C4 of the semiconductor laser array 100 are not operated, an optical waveform outputted from the first channel C1 is defined as a first optical waveform. Next, in the case where only the first channel C1 and the second channel C2 of the semiconductor laser array 100 are operated and the third and fourth channels C3, C4 are not operated, an optical waveform outputted from the first channel C1 is defined as a second optical waveform. In this case, the potential at the common electrode in the semiconductor laser array 100 is changed by operating the second channel C2. This change exerts a negative effect on the operation of the first channel C1, and the second optical waveform deteriorates much more than the first optical waveform. In other words, as compared to the case where only one channel is driven, when the one channel and another channel are driven, the optical waveform of the former channel deteriorates, that is, crosstalk occurs.

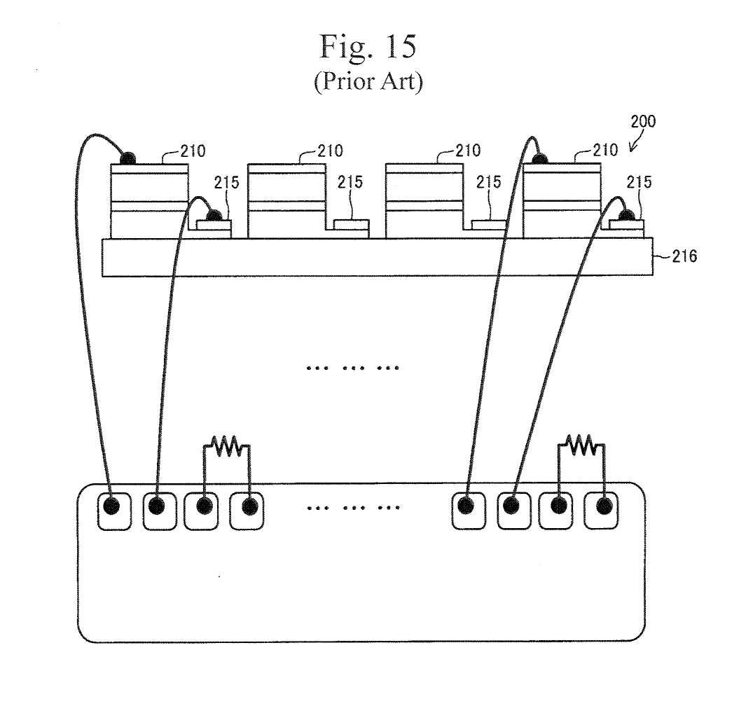

Meanwhile, in order to suppress the above-mentioned crosstalk between the channels, as shown in FIG. 15, there is provided a method of using a polarity separation-type semiconductor laser array 200 in which an N-side electrode 215 is separated from each semiconductor laser 210 and formed on an insulating substrate 216. However, according to this method, configuration of the semiconductor array laser 200 is complicated and difficult to manufacture, disadvantageously leading to an increase in costs. In addition, this method causes problems such as long-term reliability and limitation of environment temperatures.

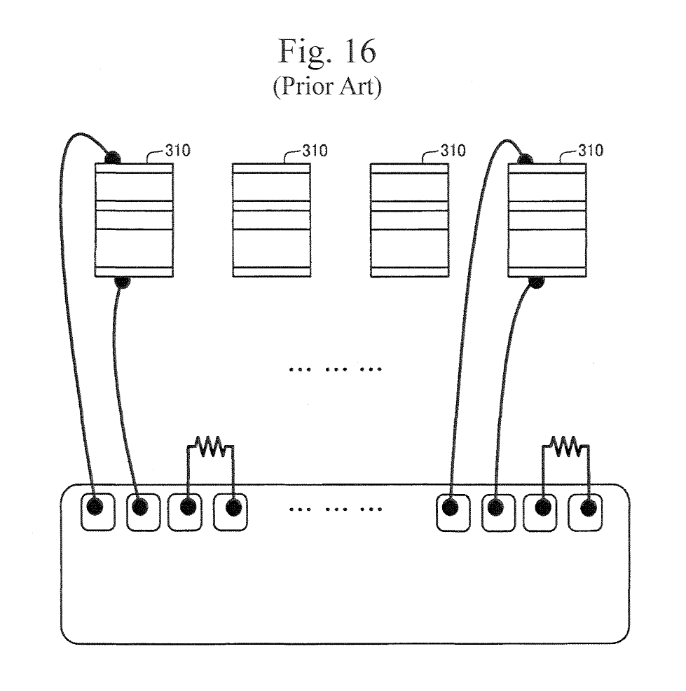

In order to suppress the above-mentioned crosstalk between the channels, as shown in FIG. 16, there is also provided a method of arranging a plurality of semiconductor lasers 310 in close contact with one another. However, such method of arranging the plurality of semiconductor lasers 310 causes problems that mounting costs are high and miniaturization of the optical module is difficult.

On the contrary, as described in First embodiment, the parallel-arranged type optical module in accordance with this embodiment has a unique characteristic to connection between the semiconductor laser and the semiconductor laser driver IC.

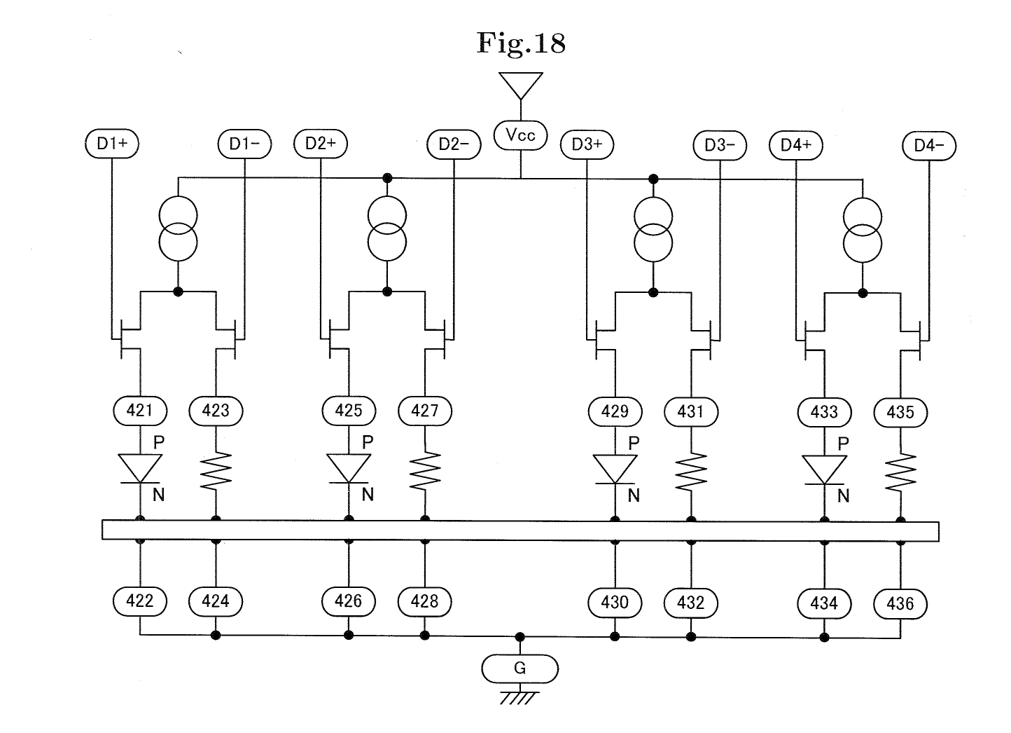

Specifically, as shown in FIG. 17 and FIG. 18, the parallel-arranged type optical module in this embodiment includes a semiconductor laser array 400 having a common electrode formed by combining N-type semiconductor substrate 414 of a plurality of semiconductor lasers 410 with an N-side electrode 415 in an integral fashion. In a semiconductor laser driver IC 420 in this embodiment, for the semiconductor lasers 410, that is, channels C1 to C4, terminals 421 to 436 connected to corresponding electrodes of the semiconductor lasers 410 are provided.

Describing an electrical connection state of the semiconductor lasers 410 and the semiconductor laser driver IC 420, in the channels C1 to C4, the positive terminals 421, . . . , 433 for the non-inverted data (D+) each are connected to the P-side electrode of each semiconductor laser 410 and the negative terminals 422, . . . , 434 for the non-inverted data (D+) each are connected to the common electrode 415 in the semiconductor laser array 400. In the channels C1 to C4, the positive terminals 123, . . . , 135 for the inverted data (D−) each are connected to the common electrode 415 in the semiconductor laser array 400 through a resistor 460 and the negative terminal 424, . . . , 436 for the inverted data (D−) each are connected to the N-side common electrode 415 in the semiconductor laser array 400.

By connecting the semiconductor laser array 400 to the semiconductor laser driver IC 420 as described above, a DC current flows between the N-side electrode 415 forming the common electrode for the semiconductor lasers 410 and each of the terminals 421 to 436 in the semiconductor laser driver IC 420, resulting in that the potential at the common electrode in the semiconductor laser array 400 is kept constant. Whereby, even another channel, in addition to an initial channel, is driven, it is possible to prevent occurrence of crosstalk that the optical waveform of the initial channel deteriorates.

Although configuration of the four channels of semiconductor laser array has been described above, the number of channels of the semiconductor laser array in the parallel-arranged type optical module according to the present invention is not limited to four, and the semiconductor laser array may be constituted of a plurality of channels such as eight channels and 12 channels. In the configuration shown in FIG. 17 and other figures, the resistor 460 is not necessarily provided. In place of the resistor 460, the dummy semiconductor laser or the Peltier element may be connected as in First to Third modification examples of First embodiment, or only the bonding wires may be used without providing any electronic component between the semiconductor laser array and the semiconductor laser driver IC.

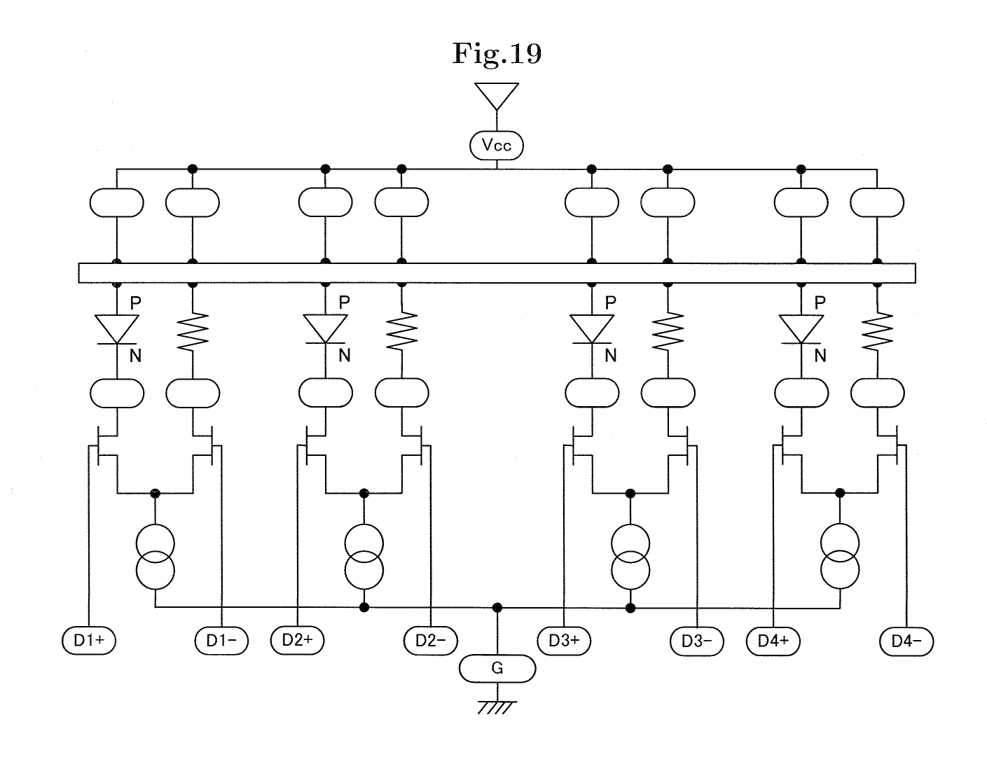

Next, FIG. 19 is a circuit diagram of a modification example of the parallel-arranged type optical module in accordance with Second embodiment. The parallel-arranged type optical module shown in FIG. 19 is different from the parallel-arranged type optical module shown in FIG. 18, the P-side electrode and the N-side electrode in each semiconductor laser 410 are reversed, and the positive terminals 421, . . . for the non-inverted data (D+) and the negative terminals 422, . . . for the inverted data (D−) in the semiconductor laser driver IC 420 are reversed. That is, the present invention can be applied to both the semiconductor laser with N-substrate and the semiconductor laser with P-substrate.

Specifically, as in the example shown in FIG. 19, describing an electrical connection state of the semiconductor laser array having a common P-side electrode to the semiconductor laser driver IC, the positive terminal for the non-inverted data (D+) in each channel is connected to the P-side electrode in the semiconductor laser array and the negative terminal for the non-inverted data (D+) is connected to the N-side electrode in each semiconductor laser. The positive terminal for the inverted data (D−) is connected to the P-side electrode in the semiconductor laser array and the negative terminal for the inverted data (D−) is connected to the P-side electrode in the semiconductor laser array through a resistor. The resistor is not necessarily provided. In place of the resistor, the dummy semiconductor laser or the Peltier element may be connected as in First to Third modification examples of First embodiment, or only the bonding wires may be used without providing any electronic component between the semiconductor laser array and the semiconductor laser driver IC.

Even with the above-mentioned configuration, since the potential at the common electrode in the semiconductor laser array is kept constant, occurrence of crosstalk can be prevented.

### Third Embodiment

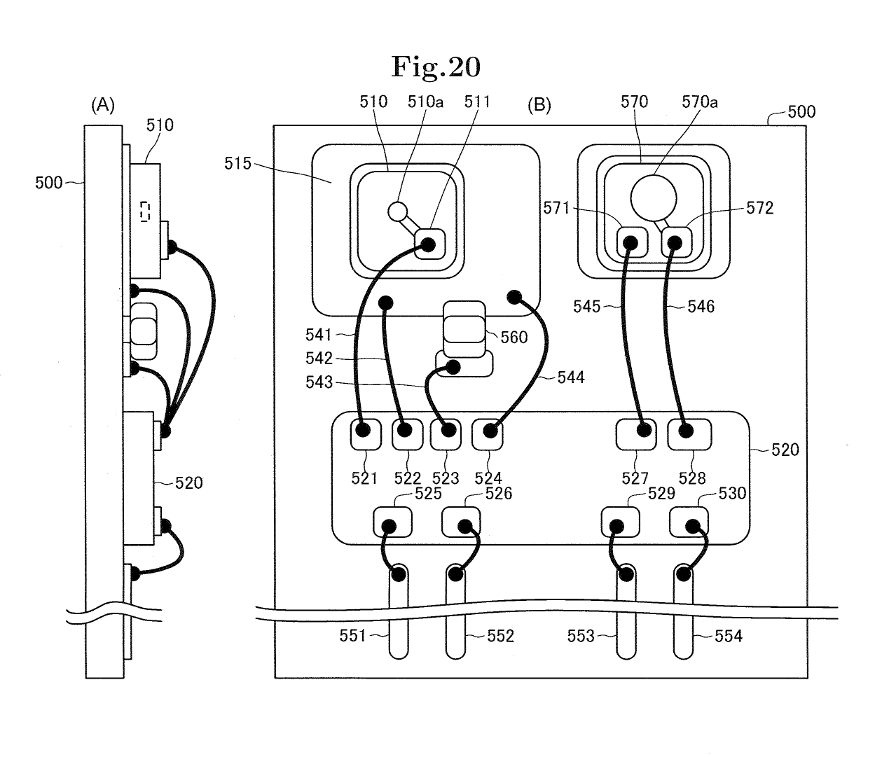

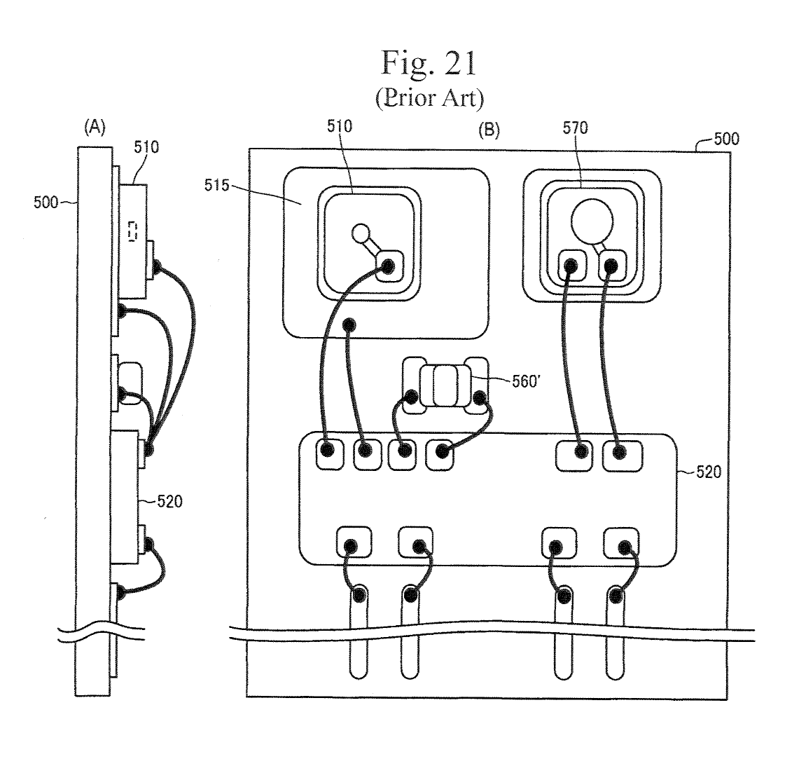

Next, Third embodiment of the present invention will be described below with reference to FIG. 20 and FIG. 21. FIG. 20 is a view showing configuration of an optical module in accordance with this embodiment and FIG. 21 is a view showing configuration of an optical module to be compared with the optical module in this embodiment.

The optical module in this embodiment includes a light-receiving element that receives the optical signal outputted from the semiconductor laser in addition to the configuration of the optical module described in First embodiment. That is, the optical module in this embodiment functions as a light transmitter-receiver.

Specifically, the optical module in this embodiment has similar configuration to that described in First embodiment and includes a light-receiving element 570 mounted at a position adjacent to a semiconductor laser 510 on a substrate 500. The light-receiving element 570 has a light-receiving aperture 570a that receives light and terminals 571, 572 that output a current signal based on the received optical signal. A distance between a laser optical output window 510a in the semiconductor laser 510 and the light-receiving aperture 570a in the light-receiving element 570 is, for example, 250 μm or 500 μm.

A driver IC 520 having a function of driving the semiconductor laser and a function of driving the light-receiving element includes terminals 521 to 526 connected to electrodes of the semiconductor laser 510 and trace lines 551, 552 for data input and terminals 527 to 530 connected to the light-receiving element 570 and trace lines 553, 554 for outputting data from the light-receiving element 570.

The semiconductor laser 510 is connected to the driver IC 520 as in First embodiment. Thus, the semiconductor laser 510 is driven with a modulated (AC) current according to a data pattern of a digital electric signal inputted from the data input trace lines 551, 552 to the Din+ terminal 525 and the Din− terminal 526 in the driver IC 520 to output an optical signal to the outside.

Describing a connection state of the light-receiving element 570 and the driver IC 520, the output terminals 571, 572 in the light-receiving element 570 are connected to the terminals 527, 528 in the driver IC 520 via bonding wires 546, 546, respectively, and the Dout+ terminal 529 and the Dout− terminal 530 in the semiconductor laser driver IC 520 are connected to the data output trace lines 553, 554, respectively. Whereby, the light-receiving element 570 receives an optical signal inputted from the outside and outputs a modulated (AC) current according to the optical signal pattern to the data output trace lines 553, 554 as a digital (electric) signal data pattern.

Here, it is considered that the connection state of the semiconductor laser 510 and the driver IC 520 is a state shown in FIG. 21, that is, the state in FIG. 1, which is described in BACKGROUND ART. In such case. since the AC current flows to an electrode pad 515 in the semiconductor laser 510, an electromagnetic wave is emitted from this site. When the light-receiving element 570 is arranged adjacent to the semiconductor laser 510 in such situation, there occurs a problem that the electromagnetic wave mixes into a received signal current of the light-receiving element 570 and the driver IC 520 cannot accurately convert the received signal from the light-receiving element 570 into the digital electric signal so that the reception sensitivity of the light-receiving element increases. A driving current of the semiconductor laser 510 is about 6 mA to 10 mA, while the signal current from the light-receiving element 570 in the order of μA in the minimum case. For this reason, increasing of the reception sensitivity is a highly serious problem.

On the contrary, with the configuration according to the present invention as shown in FIG. 20, since the DC current flows to the electrode pad 515 in the semiconductor laser 510, no electromagnetic wave is generated from the electrode pad 515 in the semiconductor laser 510. As a result, the reception level of the optical signal by the light-receiving element 570 can be prevented from increasing.

The semiconductor laser and the driver IC that mounted in the optical module in this embodiment may be any of semiconductor lasers and semiconductor laser driver ICs that are described in the above-mentioned other embodiments.

1. An optical module comprising:
a semiconductor laser including a P-side electrode and an N-side electrode; and
a semiconductor laser driver circuit that drives the semiconductor laser so as to output an optical signal from the semiconductor laser according to a pattern of a differentially transmitted digital electric signal,
the semiconductor laser driver circuit including a positive-side terminal and a negative-side terminal for differentially transmitted non-inverted data, and a positive-side terminal and a negative-side terminal for differentially transmitted inverted data,
one terminal for the non-inverted data being electrically connected to one electrode of the semiconductor laser and the other terminal for the non-inverted data, and
one terminal for the inverted data and the other terminal for the inverted data each being connected to the other electrode of the semiconductor laser; and
an electronic component having a predetermined resistance value electrically connected between one terminal for the inverted data that has the same polarity as one terminal for the non-inverted data in the semiconductor laser driver circuit, the one terminal for the non-inverted data being connected to the one electrode in the semiconductor laser and the other electrode in the semiconductor laser.

2. The optical module according to claim 1, wherein the terminals in the semiconductor laser driver circuit each are connected to the corresponding electrode of the semiconductor laser via a signal line having a predetermined length.

3. The optical module according to claim 1, wherein:
the other terminal for the non-inverted data is electrically connected to the other electrode of the semiconductor laser directly via a signal line having a predetermined length, and
the other terminal for the non-inverted data having the same polarity as the other terminal for the non-inverted data is connected to other electrode of the semiconductor laser via a signal line having a predetermined length.

4. The optical module according to claim 1, wherein the electronic component is a resistor having a resistance value corresponding to that of the semiconductor laser.

5. The optical module according to claim 1, wherein the electronic component is another semiconductor laser having the same characteristics as the initial semiconductor laser.

6. The optical module according to claim 1, wherein:
the electronic component is a Peltier element,
the Peltier element is arranged on a back surface of a substrate, the back surface being an opposite side of a front surface of the substrate on which the semiconductor laser is mounted, so as to be located corresponding to the semiconductor laser, the Peltier element being electrically connected to the one terminal for the inverted data via a through-hole electrode formed on the substrate, and being electrically connected to the other electrode in the semiconductor laser, and
a heat-absorbing part constituting the Peltier element is brought into contact with the back surface on the opposite side of the front surface of the substrate on which the semiconductor laser is mounted, and a heat-generating part constituting the Peltier element is provided with a heat-radiating plate.

7. The optical module according to claim 1, wherein:
the one electrode in the semiconductor laser is the P-side electrode and the other electrode is the N-side electrode,
the one terminal for the non-inverted data in the semiconductor laser driver circuit is the positive-side terminal and the other terminal for the non-inverted data in the semiconductor laser driver circuit is the negative-side terminal, and
the one terminal for the inverted data in the semiconductor laser driver circuit is the positive-side terminal and the other terminal for the inverted data in the semiconductor laser driver circuit is the negative-side terminal.

8. The optical module according to claim 1, wherein:
the one electrode in the semiconductor laser is the N-side electrode and the other electrode is the P-side electrode,
the one terminal for the non-inverted data in the semiconductor laser driver circuit is the negative-side terminal and the other terminal for the non-inverted data in the semiconductor laser driver circuit is the positive-side terminal, and
the one terminal for the inverted data in the semiconductor laser driver circuit is the negative-side terminal and the other terminal for the inverted data in the semiconductor laser driver circuit is the positive-side terminal.

9. The optical module according to claim 1, wherein a light-receiving element is provided adjacent to the semiconductor laser, the light-receiving element being electrically connected to the semiconductor laser driver circuit.

10. A parallel-arranged type optical module in which a plurality of optical modules are arranged in parallel, the optical modules each including:
a semiconductor laser including a P-side electrode and an N-side electrode, and
a semiconductor laser driver circuit that drives the semiconductor laser so as to output an optical signal according to a pattern of a digital electric signal differentially transmitted from the semiconductor laser,
wherein in each of the optical modules,
the semiconductor laser driver circuit has a positive-side terminal and a negative-side terminal for differentially transmitted non-inverted data, and a positive-side terminal and a negative-side terminal for differentially transmitted inverted data,
one terminal for the non-inverted data is electrically connected to one electrode in the semiconductor laser and the other terminal for the non-inverted data,
one terminal for the inverted data and the other terminal for the inverted data each are connected to the other electrode in the semiconductor laser, and
an electronic component having a predetermined resistance value electrically connected between one terminal for the inverted data that has the same polarity as one terminal for the non-inverted data in the semiconductor laser driver circuit is provided, the one terminal for the non-inverted data being connected to the one electrode in the semiconductor laser and the other electrode in the semiconductor laser.

11. The parallel-arranged type optical module according to claim 10, wherein the other electrode in each of the optical modules is formed of a common electrode.

12. The parallel-arranged type optical module according to claim 10, wherein:
the other terminal for the non-inverted data is electrically connected to the other electrode of the semiconductor laser directly via a signal line having a predetermined length, and
the other terminal for the non-inverted data having the same polarity as the other terminal for the non-inverted data is connected to other electrode of the semiconductor laser via a signal line having a predetermined length.
